(19) United States
(12) Patent Application Publication
(10) Pub. No.: US 2026/0114294 A1
(43) Pub. Date: Apr. 23, 2026

(54) Dry Etching Method by Laser Modification and Subsequent Peening as Bombarded with Metallic Glass Microparticles

(71) Applicant: Taichi Metal Material Technology Co., Ltd., Tainan (TW)

(72) Inventor: Kuan-Wei Chen, Tainan (TW)

(21) Appl. No.: 19/351,528

(22) Filed: Oct. 7, 2025

(30) Foreign Application Priority Data
Oct. 17, 2024 (TW) 113139480

(51) Int. Cl. H01L 21/48

(52) U.S. Cl. CPC H10W 70/095

(57) ABSTRACT

A dry etching method comprises firstly performing laser modification to weaken a substrate and subsequently bombarding the substrate with metallic glass microparticles at the laser-modifying area to form a recess or through hole in the substrate.

### BACKGROUND OF THE INVENTION:

As shown in FIGS. 1˜3, a conventional wet etching method for etching a substrate is disclosed as aided by laser modification. The substrate G is primarily modified and weakened at modification area M by laser modification in the substrate G as shown in FIG. 1. Then the substrate G is etched by hydrofluoric acid (etchant) A to form V-shaped taper recess H as shown in FIG. 2. The etchant then continuously corrodes or erodes the substrate G to form through hole V of venturi shape as shown on FIG. 3 to be further processed.

However, such a conventional wet etching method has the following disadvantages:
1. Whenever etching the substrate, the etchant will gradually erode the interior in the substrate along a tapering angle tapered inwardly as shown in FIG. 2. When the etching is performed from a top surface of the substrate G to form an upper recess and a bottom surface of the substrate G to form a lower recess. A venturi or the so-called “waist portion” V will then be formed after making a through hole through the upper recess and the lower recess as shown from FIG. 2 to FIG. 3. If such a through hole is further processed to be a vertical cylindrical through hole, the production complexity and cost will then be increased accordingly.
2. The tapering angle by the etchant has to do with the concentration of the etchant. A higher etchant concentration may result in a greater tapering angle. The concentration of etchant also has to do with the etching speed as effected by the etchant. The higher the etchant concentration is, the higher etching speed will be.
   So, whenever it is desired to enhance the production efficiency, the etchant concentration shall be increased so as to increase the etching speed. However, the higher etchant concentration may relatively increase the tapering angle, and such an increased tapering angle may not be allowed for a tiny work piece just requiring a small tapering angle. Therefore, it may increase the complexity to optimally control the etchant concentration, the etching speed and the tapering angles from cases to cases.
3. The etchant, such as poisonous hydrofluoric acid used in the process, may be hazardous to human health and environmental protection.
   The present inventor has found the disadvantages of the conventional etching method, and invented the present dry etching method for simplified process and better environmental protection.

### SUMMARY OF THE INVENTION

The object of the present invention is to provide a dry etching method comprising firstly performing laser modification to weaken a substrate and subsequently bombarding the substrate with metallic glass microparticles at the laser-modifying area to form a recess or through hole in the substrate.

### BRIEF DESCRIPTION OF THE DRAWINGS:

FIG. 1 shows a first step of a conventional wet etching method.

FIG. 2 shows an etched illustration after FIG. 1.

FIG. 3 shows a substrate after being formed with a through hole in the substrate.

FIG. 4 shows a first step of the present invention.

FIG. 5 shows a partially etched substrate following FIG. 4.

FIG. 6 shows the substrate as formed with a vertical through hole in the substrate in accordance with the present invention.

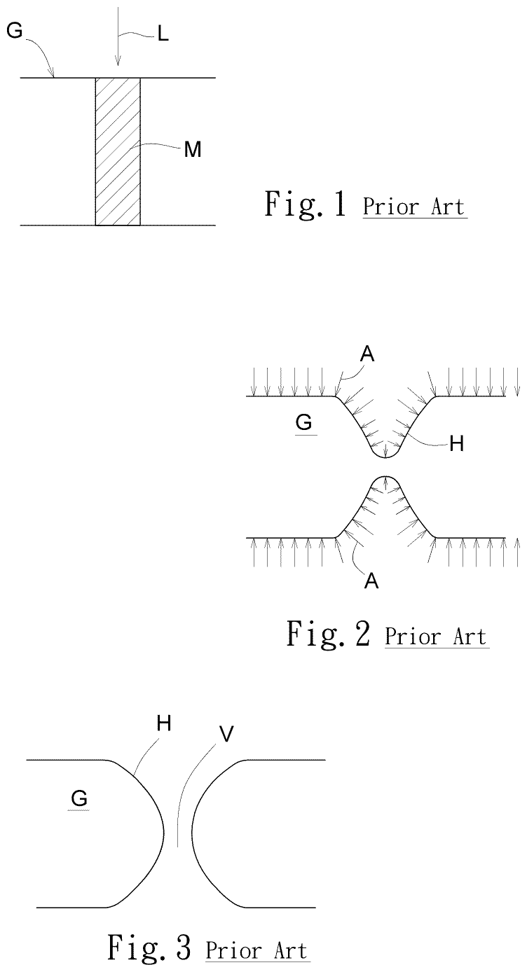

### DETAILED DESCRIPTION:

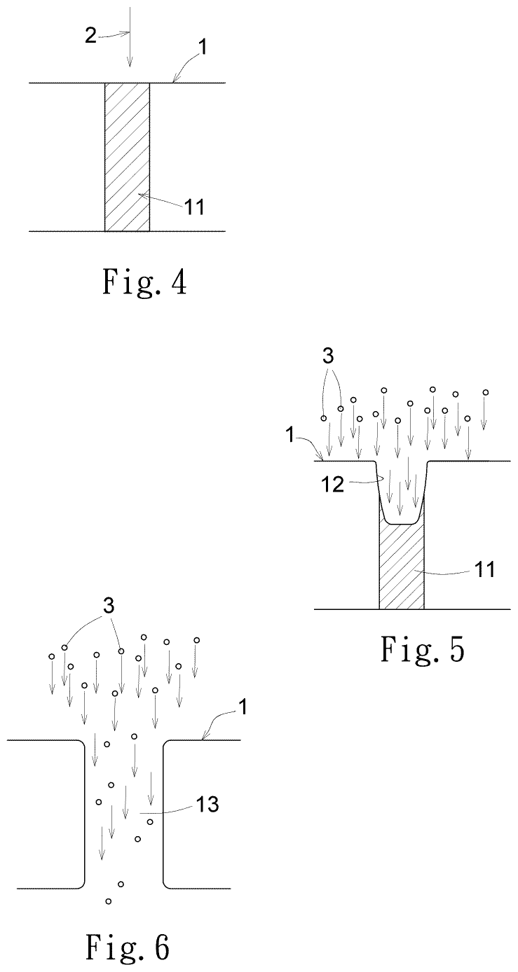

As shown in FIGS. 4˜6, the dry etching method of the present invention comprises:
A. Laser modification by applying laser 2 on the substrate 1 to form a modified area 11 of the substrate 1 as shown in FIG. 4 to weaken the substrate material. Such a modified area 11 after laser irradiation has a material strength weaker than the untreated area.
B. Peening the modified area 11 by dynamically bombarding metallic glass microparticles 3 at the modified area 11 to form a recess 12 as shown in FIG. 5. The side wall of the recess 12 may be approximately vertical.
C. The metallic glass microparticles 3 are continuously bombarding the modified area 11 not yet peened or cut to form a vertical through hole 13 through the substrate as shown in FIG. 6. Alternatively, the metallic glass microparticles 3 may be directly continuously bombarded at the modified area 11 to form a through hole 13 from FIG. 4 (Step A) to FIG. 6 (Step C), by neglecting Step B as shown in FIG. 5.

By the way, the dry etching of the present invention may be selectively applied and focused to the modified area 11, without affecting the untreated area in the substrate, to thereby obtain the desired patterns or vias, adapted for a nice micromachining.

During the laser modification, several factors, which may influence a critical value for laser modification should be considered. For instance, the laser parameters like power, wavelength and pulse duration; material properties of the substrate such as substrate type, thickness and surface condition; process parameters including speed, focal position, and assist gas, and other related factors, so as to precisely cut or drill the modified area 11, but without damaging those untreated areas in the substrate 1.

The substrate 1 may include: glass, silicon wafer, quartz, silicon nitride, silicon carbide, alumina, gallium nitride, aluminum nitride, and Zirconia.

The metallic glass microparticles have the following properties: high hardness, high real circularity, glossy surface, and small particle size (which may be equal or less than 20 microns). The surface roughness (Rz) of metallic glass microparticle is smaller than 0.1 micron. Recess cavity, ridge line or acute angles should not be formed on the particle surface so as to smoothly conduct the peening on the substrate by using the metallic glass microparticles. By means of the above-mentioned properties of the metallic glass microparticles, no breakage or cleavage will be formed on the bombarded surface of the substrate.

The hardness of the metallic glass microparticle should be higher than that of the substrate to be bombarded by the present invention.

Besides the vertical through holes as drilled by the present invention, many different tapering angles may be formed by bombarding the metallic glass microparticles on each side wall of each recess.

By properly adjusting the peening angle of the bombarding metallic glass microparticles, the side wall of the recess of the substrate may be easily formed with the desired tapering angle. The driving gas for bombarding the metallic glass microparticles includes: air, nitrogen or other inert gases. The gas driving pressure may range from 1 through 10 bars. The gas driving speed may be 200 meters per second. The operation parameters may be varied, depending upon the process requirements.

The present invention is superior to the conventional wet etching process with the following advantages:
1. The bombardment of metallic glass microparticles is directly quickly applied on the substrate without considering many operation or control parameters as required by a wet etching process. So, the process is simpler than the wet process for making a recess or a through hole or via in a substrate, especially when making recess with plural tapering angles, or making a vertical through hole or via in a substrate.
2. No poisonous acid or etchant is used in this invention for enhancing human health and environmental protection.
3. The operation and control of this invention is conducted by an easy mechanical or physical way, rather than the complex chemical ways as used in the wet etching method.
4. The metallic glass microparticles may be collected or recycled after bombardment for re-use for reducing production cost.

The present invention may significantly improve the process yield and overall manufacturing reliability, and may overcome the defects, such as the heat-affected zone (HAZ), molten burrs, and via clogging as found in a conventional laser-induced processing on a substrate, without being aided by the metallic glass microparticle bombardment as anticipated by the present invention.

The substrate as defined in the present invention may include: core substrate, coreless substrate, interposer, RDL (Redistribution Layer) interposer or RDL substrate, or other substrate members, as comprehensively used in semiconductors, glass, ceramic, optical elements, MEMS (Micro-Electro-Mechanical Systems) or any other microstructures.

I claim:

1. A dry etching method comprising:
laser modification on a substrate by laser irradiation on an area in the substrate to form a modified area in said substrate; and
bombardment of metallic glass microparticles on said modified area in said substrate to form a recess with a specific tapering angle in said substrate or a via or through hole through said substrate.

2. A dry etching method according to claim 1, wherein said metallic glass microparticle has a particle size equal or less than 20 microns.

3. A dry etching method according to claim 1, wherein said bombardment of metallic glass microparticles is driven by a gas including air, having a driving pressure ranging from 1 through 10 bars, and having a driving speed equal to or less than 200 meters per second.
